(19) United States
(12) Patent Application Publication
(10) Pub. No.: US 2018/0062115 A1
(43) Pub. Date: Mar. 1, 2018

(54) Method for Producing a Light-Emitting Device, and Light-Emitting Device

(71) Applicant: OSRAM OLED GmbH, Regensburg (DE)

(72) Inventors: Michael Popp, Köngen (DE); Ulrich Niedermeier, Leiblfing (DE); Andreas Rausch, Regensburg (DE); Nina Riegel, Tegernheim (DE); Philipp Schwamb, Regensburg (DE); Benjamin Claus Höflinger, Regensburg (DE)

(21) Appl. No.: 15/560,939

(22) PCT Filed: Mar. 17, 2016
(86) PCT No.: PCT/EP2016/055797

§ 371 Date: Sep. 22, 2017

(30) Foreign Application Priority Data
Mar. 23, 2015 (DE) 10 2015 104 318.1

(51) Int. Cl. H01L 51/52; H01L 51/56

(52) U.S. Cl. CPC H01L 51/5265; H01L 51/56; H01L 2251/5315; H01L 2251/558; H01L 51/5253

(57) ABSTRACT

A method for producing a light-emitting device and light-emitting device are disclosed. In an embodiment the method includes providing a carrier layer comprising a substrate, applying a first electrode layer, applying a layer sequence for generating light, applying a second electrode layer and structuring at least one layer for varying an optical thickness in a first region of the light-emitting device differently from the layer in a second region of the light-emitting device, wherein the second region is laterally arranged relative to the first region.

This patent application is a national phase filing under section 371 of PCT/EP2016/055797, filed Mar. 17, 2016, which claims the priority of German patent application 10 2015 104 318.1, filed Mar. 23, 2015, each of which is incorporated herein by reference in its entirety.

### TECHNICAL FIELD

A light emitting device and method for producing a light-emitting device are described.

### SUMMARY OF THE INVENTION

Embodiments provide both a method and a corresponding light-emitting device which contributes to simple production of a light-emitting device with laterally different emission characteristics.

In a first aspect, a method for producing a light-emitting device having at least two laterally arranged regions of differing optical thickness is described. The light-emitting device can, for example, be a light-emitting diode, in particular an organic light-emitting diode (OLED), or both together.

The light-emitting device extends in a vertical direction between a first primary plane and a second primary plane, and the vertical direction can extend transversely or perpendicularly to the first and/or second primary plane. The primary planes can, for example, be a top face and a bottom face of the light-emitting device. The bottom face and/or the top face can be a radiation passage face of the light-emitting device. The light-emitting device is extended two-dimensionally in a lateral direction, that is, for example, at least in some parts parallel to the primary planes, and in the vertical direction it has a thickness which is small compared to a maximum extent of the light-emitting device in the lateral direction.

In at least one embodiment in accordance with the first aspect, a carrier layer is provided. The carrier layer, for example, forms the bottom face of the light-emitting device. The carrier layer is, for example, a mechanical support structure of the light-emitting device.

In at least one embodiment in accordance with the first aspect, the carrier layer comprises a substrate of the light-emitting device. The substrate is, for example, a glass substrate, which contains a glass or consists of glass, or a polymer substrate, which contains or consists of a plastic such as a polymer. The substrate can in particular be milky-transparent or clear and transparent. Further, the substrate can be constructed flexibly, for example. In particular, for that purpose the substrate can contain, for example, a metal foil, a plastic film, and/or a thin glass, or can consist of one of these films or foils (such as polyimide films).

In at least one embodiment in accordance with the first aspect, a first electrode layer is applied to the carrier layer. The first electrode layer consists of an electrically conductive material, such as a metal or an oxide, or contains such a material. The first electrode layer can for instance be applied to the carrier by physical vapor deposition (PVD). The first electrode layer, after this step, in particular covers a surface of the carrier layer that faces away from the bottom face of the light-emitting device.

The first electrode layer is constructed as transparent, for example. In particular, the first electrode layer can have a transparent conductive oxide. Transparent conductive oxides are transparent conductive materials, as a rule, metal oxides, such as zinc oxide, tin oxide, cadmium oxide, titanium oxide, indium oxide, or indium-tin oxide (ITO). The light-emitting device can then, for example, be a so-called “bottom emitter” or a so-called “transparent OLED”. Alternatively or in addition, the first electrode layer for instance comprises nano-scale wire structures. For example, the first electrode layer in this connection has or consists of graphene.

In at least one embodiment in accordance with the first aspect, a layer sequence for generating light is applied to the first electrode layer. Applying the layer sequence can be done for instance by means of so-called inline sputtering in a physical gas phase deposition (PVD) process. The layer sequence after this step in particular covers a surface of the first electrode layer that faces away from the bottom face of the light-emitting device. The layer sequence is constructed for generating light in operation of the light-emitting device, in particular light in one or more active regions. White or colored light can be generated in the layer sequence. The layer sequence in this context for instance comprises organic layers. The light-emitting device can then in particular be an organic light-emitting diode.

In at least one embodiment in accordance with the first aspect, a second electrode layer is applied to the layer sequence. In particular, the second electrode layer is applied in such a way that the second electrode layer is not in contact with the first electrode layer. The second electrode layer consists of an electrically conductive material, or contains such a material. The second electrode layer can, for example, also be constructed as transparent. The second electrode layer can for instance, analogously to the first electrode layer, be applied to the layer sequence by means of a physical gas phase deposition process. The second electrode layer after that step in particular covers a surface of the layer sequence facing away from the bottom face of the light-emitting device.

In at least one embodiment in accordance with the first aspect, at least one layer is structured for varying the optical thickness in a first region of the light-emitting device differently from the respective layer in a further region of the light-emitting device. The further region is arranged laterally relative to the first region. The at least one layer structured for varying the optical thickness can be the first electrode layer, at least one layer of the layer sequence, the second electrode layer, or the substrate. In particular, a combination with structuring of a plurality of these layers is also conceivable.

The structuring of the at least one layer for varying the optical thickness in the first region can for instance comprise introducing an additional layer in this region. The structuring can furthermore comprise an at least partial removal, or an at least partial deformation, of the at least one layer in this region. The structuring in this context can in particular involve a separate step, which is performed for instance directly following the application of the respective layer. Alternatively or in addition, the structuring can also be done during the application of the respective layer.

In at least one embodiment in accordance with the first aspect, a carrier layer that comprises a substrate is provided. A first electrode layer, a layer sequence for generating light, and a second electrode layer are applied to the carrier layer. At least one layer, for varying the optical thickness in a first region of the light-emitting device, is structured differently from the respective layer in a further region of the light-emitting device that is arranged laterally relative to the first region.

Advantageously, this makes it simple to produce a light-emitting device that has various emission characteristics, depending on the respective regions of differing optical thickness. The emission characteristics of the light-emitting device in the respective regions can in particular differ in terms of such features as color angle course, outcoupling direction (direction-dependent intensity), index of refraction, color, luminance, brightness, emission angle, and emission angle range, wherein both a combination of these features and merely a single feature in the respective regions can be constructed differently. The term “emission characteristics,” in this context in particular, describes individual features or a combination of features which result or vary a respective appearance, for instance depending on the optical thickness for an observer of the light-emitting device.

The first region and the further region are laterally arranged, for instance side by side, so that the result for an observer of the light-emitting device from at least one direction, such as the vertical direction, is that the first region and of the further region that each differ laterally in appearance with respect to the light-emitting device, for instance depending on an operating state of the light-emitting device. The differing appearance of the respective regions of the light-emitting device can alternatively also be independent of an operating state of the light-emitting device.

For instance, for the observer, the appearance is additionally dependent on a lateral series of regions of different optical thickness. For instance, because of the lateral series, the result is a laterally extending surface piece of the light-emitting device with emission characteristics that differ from those of the remaining light-emitting device, in particular from a surface piece having a different lateral series of regions of different optical thickness.

In at least one embodiment in accordance with the first aspect, an interlayer is introduced into the layer sequence for varying the optical thickness of the first region. The interlayer then extends laterally over the first region. In particular, the interlayer is constructed as transparent. The interlayer can be a metal layer, which for instance contains a material such as aluminum or consists of that material. The interlayer in this context, in the vertical direction, is in particular surrounded by material of the layer sequence. Furthermore, the interlayer has a thickness in the vertical direction that is low compared to a thickness of the layer sequence in the vertical direction. The thickness of the interlayer in this context can amount for instance to between 0.2 nm and 5 nm, in particular 2 nm. For example, the interlayer in this context is applied by vapor deposition.

The interlayer has the effect for instance that in an off state of the light-emitting device, a color angle course for the observer of the light-emitting device is established in the respective region over which the interlayer extends laterally. In other words, a color of the respective region as perceived by the observer depends on an angle that the observer forms with a light exit face of the respective region of the light-emitting device. Advantageously, such a light-emitting device can be produced especially simply and economically.

In at least one embodiment in accordance with the first aspect, a thickness in the vertical direction of at least one layer in the first region is constructed differently from a thickness in the vertical direction of the respective layer in the further region. The differing thickness in the vertical direction has the effect, for instance, that for the observer, a brightness and/or color of the respective regions differs from one another. For instance, this is achieved by differing travel paths of light emitted by the respective layer, so that at differing wavelengths of the light, for instance, constructive or destructive interference occurs.

In at least one embodiment in accordance with the first aspect, a growth rate for applying the respective layer in the first region is different from a growth rate for applying the respective layer in the further region. Advantageously, the thickness of the respective layer in the vertical direction can thus be especially simple, in particular, it can be varied laterally without additional method steps, in order to generate said structuring. In this context, the growth of the first region can for instance be retarded. For instance, a processing speed in inline vapor deposition for applying the layer sequence can be varied as a function of the respective region, for instance by a factor of 2.

In at least one embodiment in accordance with the first aspect, the at least one layer in the first region is at least partially deformed or in the vertical direction at least partially removed. Advantageously, the thickness of the respective layer in the vertical direction can be laterally varied especially economically. For instance, a surface of the respective layer can be subjected to coherent radiation, for instance by a laser, for this purpose. Alternatively, the surface of the respective layer can for instance be mechanically structured, for instance by means of sandblasting or embossing, that is, an impressing or stamping process.

In at least one embodiment in accordance with the first aspect, an auxiliary layer is applied to a side of the light-emitting device facing away from the carrier layer. The auxiliary layer forms the top face, for example, of the light-emitting device. The auxiliary layer can be constructed in a single layer or in multiple layers. The auxiliary layer or a partial layer thereof can be constructed as a protective layer, which for instance protects the light-emitting device against mechanical damage and/or seals it off hermetically. The auxiliary layer or a partial layer thereof can furthermore be constructed as a connecting layer for a firmly bonded connection, for instance between an electrode layer and a substrate. The auxiliary layer or a partial layer thereof can furthermore comprise a thin-film coating or be constructed as a so-called “cavity encapsulation”, that is, encapsulation with a glass cavity. In this context, the auxiliary layer or a partial layer thereof can consist of or have a material such as SiNOx and ATO (such as AlOx/TiOx), as a layer structure for thin-film encapsulation.

The auxiliary layer or a partial layer thereof can for instance also be constructed as electrically insulating. The auxiliary layer or a partial thereof can furthermore be constructed as a mirror layer for the light generated in the layer sequence. In that case, the light-emitting device is for instance a so-called “bottom emitter”. The auxiliary layer can furthermore be constructed as transparent. In that case, the light-emitting device is for instance a so-called “top emitter” or a so-called “transparent OLED”. Furthermore, the auxiliary layer or a partial layer thereof can in this context be constructed as light-scattering.

In at least one embodiment in accordance with the first aspect, the auxiliary layer comprises a substrate. The substrate is for instance a glass substrate or a polymer substrate. In particular, the substrate is constructed as transparent. The substrate can in particular be constructed analogously to the substrate assigned to the carrier layer.

In at least one embodiment in accordance with the first aspect, a first microcavity structure on a surface of the substrate in the first region is constructed for varying the optical thickness. The surface of the substrate then is in particular a light exit face of the light-emitting device. In particular, the substrate assigned to the carrier layer and/or the substrate assigned to the auxiliary layer can have the first microcavity structure. For instance, the surface of the substrate can be subjected for this purpose to coherent radiation, for instance by a laser. Alternatively, the surface of the substrate can be structured mechanically, for instance, such as by means of sandblasting or embossing.

The first region having the first microcavity structure can in particular be a surface piece with a lateral series of portions of the surface piece that are of differing optical thickness. In this context, the appearance of the first region, for the observer, is varied in particular by means of the lateral series of portions. The first region, in other words, comprises a multiplicity of laterally adjacent portions of differing optical thickness. The lateral series of portions in the first region differs in particular from a laterally adjacent further region of the light-emitting device, so that the respective regions can also be called regions of differing optical thickness.

Advantageously, a light-emitting device of this kind can be produced simply and economically. A lateral extent of the portions can for instance amount to between 40 μm and 50 μm, in particular with embossing. Furthermore, the lateral extent of the portions can amount to 10 μm, in particular when the surface of the substrate is subjected to coherent radiation.

In at least one embodiment in accordance with the first aspect, a second microcavity structure is constructed inside the substrate in the first region for varying the optical thickness. The second microcavity structure can for instance be constructed with a microlaser.

The first region having the second microcavity structure can in particular be a surface piece with a lateral series of portions of the surface piece of differing optical thickness. In this connection, the appearance of the first region, for the observer, is varied in particular by the lateral series of the portions. The first region, in other words, comprises a multiplicity of laterally adjacent portions of differing optical thickness. The lateral series of portions in the first region then differs in particular from a laterally adjacent further region of the light-emitting device, so that the respective regions can also be called regions of differing optical thickness. A lateral extent of the portions can for instance amount to between 1 μm and 2 μm. Advantageously, this makes an especially sharp resolution of the appearance of a boundary of the first region possible for the observer.

In a second aspect, a light-emitting device having at least two laterally arranged regions of differing optical thickness is described. In particular, the light-emitting device can be produced by a method, described here, in accordance with the first aspect, so that all the features disclosed for the method are also disclosed for the light-emitting device, and vice versa.

In at least one embodiment in accordance with the second aspect, the light-emitting device has a carrier layer, which comprises a substrate. The light-emitting device further has a first electrode layer, a layer sequence for generating light, and a second electrode layer. The carrier layer, the first electrode layer, the layer sequence, and the second electrode layer are arranged one above the other in the vertical direction. An optical thickness of at least one layer in a first region of the light-emitting device is constructed differently from an optical thickness of the respective layer in a further region of the light-emitting device that is laterally arranged relative to the first region.

In at least one embodiment in accordance with the second aspect, the layer sequence has the same composition for generating light in all the laterally arranged regions. In particular, the same emitter material is used in all the laterally arranged regions. This means, in particular, that if in operation, light of a color differing from one another is emitted by two different lateral regions, the reason is not the use of different emitter materials in the regions. Instead, the same emitter material is used in the regions, and the layer sequence for generating light has the same composition in the regions. It is then also possible for the layer sequence for generating light to extend without interruption over two of the laterally arranged regions, and in particular over all of the laterally arranged regions. In that case, not every one of the regions is assigned its own layer sequence for generating light, the layer sequence being separated, for example, by electrically insulating material, from the layer sequences for generating light of other regions. Instead, in this case two or more of the regions share a layer sequence for generating light.

In at least one embodiment in accordance with the second aspect, the layer sequence comprises an interlayer for varying the optical thickness that extends laterally over the first region. The interlayer extends laterally over the first region. In particular, the interlayer is constructed of or has a metal, such as aluminum. In the vertical direction, the interlayer is surrounded by material of the layer sequence. A thickness of the interlayer in the vertical direction amounts to 2 nm, for example. The interlayer is in particular constructed as transparent.

In at least one embodiment in accordance with the second aspect, a thickness in the vertical direction of at least one layer in the first region is constructed differently from a thickness in the vertical direction of the respective layer of the further region.

In at least one embodiment in accordance with the second aspect, the light-emitting device has an auxiliary layer, which comprises a substrate. The auxiliary layer is arranged on a side of the light-emitting device facing away from the carrier layer. In particular, the substrate can be constructed analogously to the substrate assigned to the carrier layer.

In at least one embodiment in accordance with the second aspect, a surface of the substrate has a first microcavity structure in the first region. The surface of the substrate in the first region is constructed differently from a surface of the substrate in the further region. The first region having the first microcavity structure can in this context comprise a multiplicity of laterally adjacent portions of different optical thickness. The surface of the substrate is in particular a light exit face of the light-emitting device.

For instance, the substrate assigned to the carrier layer and/or the substrate assigned to the auxiliary layer can have the first microcavity structure. The multiplicity of laterally adjacent portions in the first region, and in particular their lateral series, differs, in particular from a laterally adjacent further region of the light-emitting device, so that the respective regions can also be called regions of differing optical thickness.

In at least one embodiment in accordance with the second aspect, the substrate in the first region has a second microcavity structure. The substrate is constructed differently in the first region from the substrate in the further region. The first region having the second microcavity structure can in this context comprise a multiplicity of laterally adjacent portions of differing optical thickness. For instance, the substrate assigned to the carrier layer and/or the substrate assigned to the auxiliary layer has the second microcavity structure. The plurality of laterally adjacent portions in the first region, and in particular their lateral series, differs, in particular from a laterally adjacent further region of the light-emitting device, so that the respective regions can also be called regions of differing optical thickness.

In at least one embodiment in accordance with the second aspect, the regions of differing optical thickness have the effect that in operation of the light-emitting device, a brightness of light emitted by the light-emitting device differs in the respective regions. Alternatively or in addition, the regions of differing optical thickness have the effect that in operation of the light-emitting device, a color of light emitted by the light-emitting device differs in the respective regions. Alternatively or in addition, the regions of differing optical thickness have the effect that in operation of the light-emitting device, a direction of light emitted by the light-emitting device differs in the respective regions.

In at least one embodiment in accordance with the second aspect, the regions of differing optical thickness have the effect that when the light-emitting device is not in operation, a brightness of light reflected by the light-emitting device differs in the respective regions. Alternatively or in addition, the regions of differing optical thickness have the effect that when the light-emitting device is not in operation, a color of light reflected by the light-emitting device differs in the respective regions. Alternatively or in addition, the regions of differing optical thickness have the effect that when the light-emitting device is not in operation, a direction of light reflected by the light-emitting device differs in the respective regions.

In at least one embodiment in accordance with the second aspect, the regions of differing optical thickness have the aforementioned effect, in particular regardless of the operating state of the light-emitting device.

In at least one embodiment in accordance with the second aspect, the number of regions of differing optical thickness amounts to less than 100. In particular, the number of regions of differing optical thickness amounts to less than ten. Advantageously, individual regions can as a result be perceived with differentiation by the observer. The light-emitting device thus differs in particular from a display device that has many pixels.

In at least one embodiment in accordance with the second aspect, a color of light emitted by the light-emitting device is the same in at least one direction in each of the regions of differing optical thickness. The appearance of the regions of the light-emitting device can thus be the same, for example, to the observer from the at least one direction for different regions, even if the optical thickness of the regions differs from one another. For example, this can be achieved by means of travel path differences of light radiated by the respective layer in the at least one direction in the respective regions, which amount to an integral multiple of a wavelength corresponding to the color. The composition of the layer sequence for generating light can then be the same in the regions of differing optical thickness. That is, in different regions, the same emitter materials are used. Thus with regard to the emitter material, each region is constructed for generating light of the same color.

In at least one embodiment in accordance with the second aspect, a composition of at least one of the layers, and in particular all the layers, in the regions of differing optical thickness is the same. The individual regions, in other words, thus differ not because of additional layers and/or a different series of layers and/or a different choice of material for the layers, but rather as a result of the structuring of the at least one layer.

In at least one embodiment in accordance with the second aspect, the light-emitting device has at least two segments arranged laterally and capable of being operated separately from one another. The segments are in particular light-emitting segments of the light-emitting device, having as an example different brightness or different. For that purpose, the segments are provided for instance with separate electrodes, which can be operated via separate supply lines at various current intensities. In this context, at least one of the electrode layers has a segmentation pattern, as a result of which the respective electrode layer is subdivided into separate electrodes. The segmentation pattern can have an arbitrary two-dimensional form, such as a geometric basic form or the form of a graphic symbol. The segmentation pattern can equally well be constructed in gridlike fashion, for instance, on the order of a polygonal grid.

In at least one embodiment in accordance with the second aspect, at least one region is assigned to at least one segment. In particular, an emission characteristic of the at least one segment in the at least one region can be adapted as a result. Advantageously, this contributes for instance to improved perception of the at least one segment. For instance, the at least one segment can then comprise a plurality of regions of differing optical thickness, so that the segment has various emission characteristics.

In at least one embodiment in accordance with the second aspect, a plurality of regions of differing optical thickness is assigned to the segment. The plurality of regions are arranged in particular laterally in a pattern, for instance distributed uniformly in gridlike fashion, so that for the observer an emission characteristic brought about by the respective regions is produced for the entire segment. In particular, an emission characteristic of regions of differing optical thickness assigned to the segment, in operation of the segment, can be combined with an emission characteristic of regions of differing optical thickness assigned to the segment when the segment is not in operation. For example, this is done by means of a pulse width modulation upon triggering of the light-emitting device, so that emission effects perceived by the observer are superimposed because of very frequent alternation of the operating state.

In at least one embodiment in accordance with the second aspect, each segment is assigned precisely one region. Advantageously, this contributes, for example, to improved perception of the segment.

### BRIEF DESCRIPTION OF THE DRAWINGS

Further features, embodiments and expedient aspects will become apparent from the ensuing description of the exemplary embodiments in conjunction with the drawings.

FIG. 1 shows a first exemplary embodiment of a light-emitting device in a schematic plan view;

FIG. 2 shows the light-emitting device of FIG. 1 in a schematic sectional view; and

FIG. 3 shows a second exemplary embodiment of a light-emitting device in a schematic sectional view.

Identical, similar or identically acting elements are provided in the drawings with the same reference numerals. The drawings and the relative sizes of the elements shown in the drawings compared to one another should not be seen as being to scale. In fact, individual elements and in particular layer thicknesses may be shown exaggeratedly large for better illustration and/or better comprehension.

### DETAILED DESCRIPTION OF ILLUSTRATIVE EMBODIMENTS

A first exemplary embodiment of a light-emitting device 1 is shown in schematic plan view in FIG. 1. The light-emitting device 1 comprises two segments 1a, 1b that can be operated separately from one another and that are arranged laterally adjacent to one another. In operation of one of the two segments 1a, 1b, the picture of an arrow, for instance, appears for an observer.

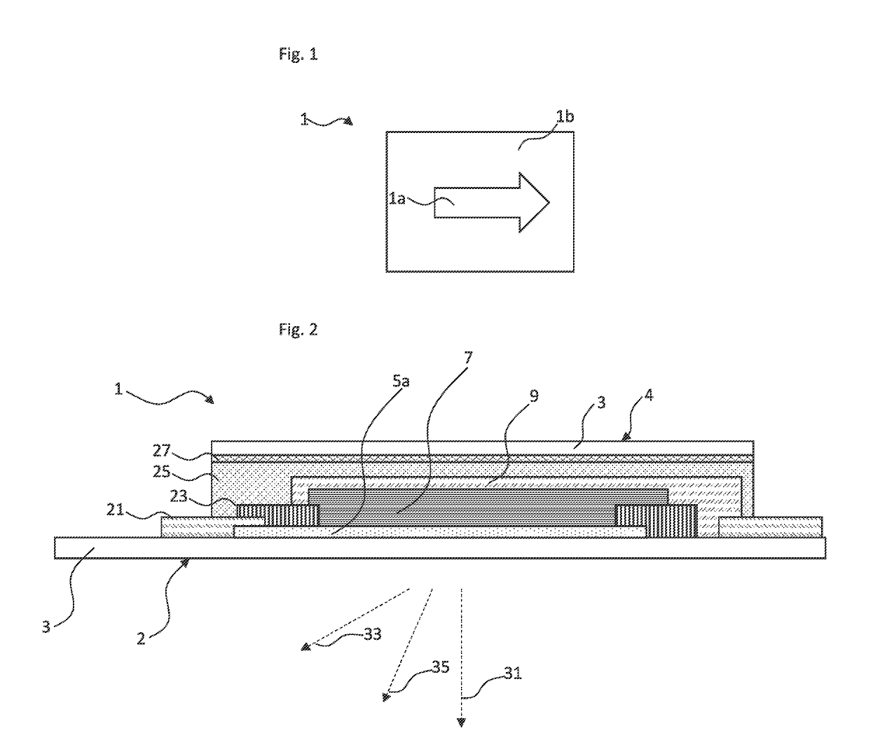

As shown in the schematic sectional view of FIG. 2, the light-emitting device 1 has a carrier layer 2, which comprises a substrate 3. The carrier layer 2 forms a bottom face of the light-emitting device 1, through which the light generated by the light-emitting device 1 (a so-called “bottom emitter”) exits. The carrier layer 2 in this context is constructed as transparent. The substrate 3 is a glass substrate, for example.

The light-emitting device 1, on a side of the carrier layer 2 facing away from the bottom face, has a first electrode layer 5a, a layer sequence 7 for generating light, and a second electrode layer 9. The first electrode layer 5a is subdivided into two separate electrodes (not shown in further detail here) for separate operation of the segments 1a, 1b.

The electrode layers 5a, 9 have a conductive oxide, metal, or metal oxide, for example, such as aluminum, silver or indium tin oxide. The electrodes 9, 11 form a cathode and anode for electrical contacting of the light-emitting device 1.

The first electrode layer 5a is constructed as transparent in particular. For example, the first electrode layer 5a in this context is constructed of indium tin oxide (ITO). In other exemplary embodiments, the first electrode layer 5a is for instance thin metal layers, metal net structures, or graphene.

The light-emitting device 1 for instance also comprises electrical contact feeders 21, which can be constructed as transparent or nontransparent. For example, the electrical contact feeders and/or the second electrode layer 9 has or consists of one of the following materials: molybdenum/aluminum (Mo/Al), molybdenum (Mo), chromium/aluminum/chromium (Cr/Al/Cr), silver/magnesium (Ag/Mg), aluminum (Al).

The layer sequence 7 comprises semi-organic semiconductor material, in particular organic layers for emitting light that contain an emitter material, and for supplying charge carriers. The light-emitting device 1 is in particular an organic light-emitting diode chip with an active region provided for generating light (for the sake of simplification of illustration, this is not explicitly shown in the drawings).

In this exemplary embodiment, the light-emitting device 1 further comprises insulator layers 23, arranged in the vertical direction between the two electrode layers 5a, 9. The insulator layers 23 are constructed of polyimide, for example. In other exemplary embodiments, the insulator layers 23 can be dispensed with, for instance in suitable masking processes.

The light-emitting device 1 in this exemplary embodiment furthermore has a coating 25. The coating 25 is, for example, a thin-film coating (TFE). Alternatively, the coating can be constructed as a so-called “cavity encapsulation”, for instance by means of SiNOx and ATO.

The light-emitting device 1 further has an auxiliary layer 4, which, for example, likewise comprises a substrate 3. The auxiliary layer 4 is arranged on a side of the light-emitting device 1 facing away from the bottom face and, for example, forms a top face of the light-emitting device 1. The auxiliary layer 4 comprises an adhesive 27, for example.

The light-emitting device 1 of FIG. 2 is in an off state, for example, in which at least the segment 1a is not in operation. The light-emitting device 1 is constructed such that for an observer in the off state, the result is the appearance of a color, for example, of the segment 1a, the segment 1b, or an entire light exit face of the light-emitting device 1, depending on the viewing direction. For example, light in a first direction 31, for example, the vertical direction, appears yellow to the observer. Light in a second direction 33, for instance the lateral direction, appears blue to the observer. The second direction 33 can, in a deviation from this, form an angle of approximately 80° with the first direction 31, for example. For example, light in a further direction 35, between the first direction and the second direction 31, 33, can assume an arbitrary further color, for example, green, depending on an observation angle.

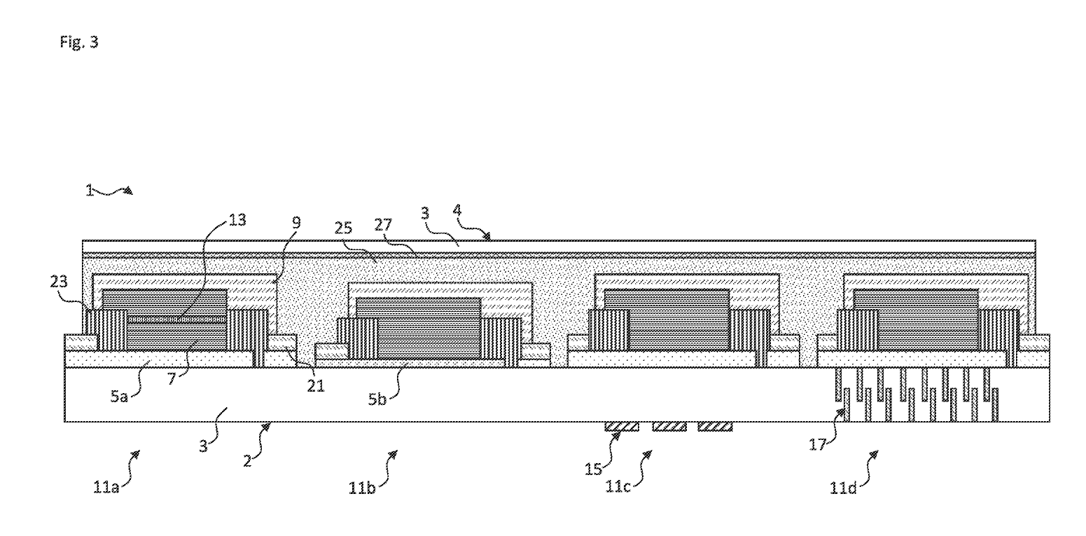

For that purpose, at least one layer 3, 5a, 7, 9 of the light-emitting device 1 has structuring for varying an optical thickness of the light-emitting device 1, as will be explained hereinafter in conjunction with FIG. 3.

FIG. 3 shows a second exemplary embodiment of a light-emitting device 1 in a schematic sectional view. The second exemplary embodiment represents various possibilities for the aforementioned structuring, which can be constructed both individually and in combination in a light-emitting device, for instance as shown in FIG. 1. For example, in this context, four laterally arranged regions 11a, 11b, 11c, 11d of differing optical thickness are shown, each with a possible form of the structuring. In particular, it would be conceivable for the possibilities shown to be combined in the vertical direction as well.

For varying the optical thickness, the light-emitting device 1 in the first region 11a has an interlayer 13, which extends laterally over the first region 11a. The interlayer 13 is arranged in particular in the layer sequence 7 and is surrounded in the vertical direction by material of the layer sequence 7. It is possible for the same emitter material to be used in the layer sequence 7 in each of the regions 11a, 11b, 11c, 11d of differing optical thickness. The interlayer is in particular a transparent metal layer, which can be vapor deposited, for instance. The interlayer 13 is constructed of aluminum, for instance, the thickness of which amounts to 2 nm, for example, in the vertical direction. The interlayer 13 has the effect for instance that the color angle course described in conjunction with FIG. 2 results for the observer when the light-emitting device 1 is in the off state. For example, additionally or alternatively, the interlayer 13 can engender a change in color or brightness.

The first region 11a, for example, has one shape. For instance, the first region can for that purpose assume the shape of the segment is (see FIG. 1). In particular, the first region 11a can be assigned to the segment 1a, so that the image of the arrow can be perceived by an observer, for instance both in operation of the light-emitting device 1 and in an off state of the light-emitting device 1. In this context, a region assigned to the segment 1b has an emission characteristic different from the first region 11a. In particular, for this purpose, the layer sequence 7 for varying the optical thickness in the region assigned to the segment 1b is constructed differently from the layer sequence 7 in the laterally adjacent first region 11a.

For varying the optical thickness, a first electrode layer 5b of the light-emitting device 1, in the second region 11b, has a thickness in the vertical direction that differs from the thickness in the vertical direction of the first electrode layer 5a in the first region 11a. In particular, the first electrode layer 5b, differing in thickness in the vertical direction, extends laterally over the second region 11b. This has the effect that travel paths passing through the respective first electrode layer 5a, 5b differ in the regions 11a, 11b. Advantageously, the result, for instance depending on a wavelength of the light, is constructive and/or destructive interferences, which leads to what for the observer is a different perceptible color and/or brightness in the respective regions 11a, 11b. This effect can for instance occur independently of an operating state of the light-emitting device 1.

In other exemplary embodiments, alternatively or in addition, a thickness in the vertical direction of the layer sequence 7 can differ in the respective regions 11a, 11b. It is furthermore conceivable that alternatively or in addition, a thickness in the vertical direction of the second electrode layer 9 differs in the respective regions 11a, 11b. In this case, the light-emitting device 1 is then, for example, a so-called “top emitter” or a so-called “transparent OLED”.

The differing thickness in the vertical direction of the corresponding layer in the respective regions 11a, 11b can be achieved for instance by changing the growth rates of the layer in the respective regions 11a, 11b.

For varying the optical thickness, the substrate 3 of the light-emitting device 1, assigned to the carrier layer 2, in the third region 11c has a first microcavity structure 15 on its surface. Constructing the first microcavity structure 15 comprises for instance applying material and/or deforming and/or removing the substrate 3 in the third region 11c. For example, the surface can for this purpose be subjected to coherent radiation or sandblasting. Alternatively or in addition, a kind of relief can be generated on the surface of the substrate 3 by means of embossing. In particular, the first microcavity structure 15 comprises a plurality of laterally adjacent partial faces of different optical thickness. For example, in FIG. 3, three partial faces are shown having a first optical thickness; they are separated laterally from one another by two partial faces of a second optical thickness. A lateral extent of partial faces generated by application or deformation can amount for instance to 40 μm to 50 μm. A lateral extent of partial faces generated by removal can for instance amount to 10 μm.

The laterally adjacent partial faces in particular form a pattern or rather an ordered structure, so that an emission characteristic of the light-emitting device 1 in the third region 11c is varied. In particular in this context, a light outcoupling in the third region 11c relative to the first region 11a can differ in brightness and/or color and/or angle. Furthermore, an index of refraction can differ in the regions 11a, 11c.

Alternatively, for instance in the event that the light-emitting device 1 is constructed as a “top emitter”, or in addition, for instance in the case that the light-emitting device 1 is constructed as a “transparent OLED”, the substrate 3 assigned to the auxiliary layer 4 can have the first microcavity structure 15.

For varying the optical thickness, the substrate 3 of the light-emitting device 1 in the fourth region 11d, which substrate is assigned to the carrier layer 2, has a second microcavity structure 17. Constructing the second microcavity structure 17 in particular comprises constructing channels inside the substrate 3 in the fourth region 11d. For example, for that purpose the substrate 3 can be subjected to coherent radiation. The second microcavity structure 17 analogously to the third region 11c in particular comprises a plurality of laterally adjacent partial faces of differing optical thickness. A lateral extent of the partial faces can for instance amount to 1 μm.

In this context, because of the greater lateral extent, what for the observer is a perceptible edge of the third region 11c has a coarser resolution than an edge of the fourth region 11d, for instance.

The laterally adjacent partial faces in particular form a pattern or rather an ordered structure, so that an emission characteristic of the light-emitting device 1 in the third region 11c is varied. In particular in this context, a light outcoupling in the fourth region 11d relative to the first region 11a can differ in brightness and/or color and/or angle. Furthermore, an index of refraction can differ in the regions 11a, 11d.

Alternatively, for instance in the event that the light-emitting device 1 is constructed as a “top emitter”, or in addition, for instance in the case that the light-emitting device 1 is constructed as a “transparent OLED”, the substrate 3 assigned to the auxiliary layer 4 can have the second microcavity structure 17.

The construction of the light-emitting device 1 and the effect achieved in the regions 11b, 11c, 11d was in each case set in relation to the first region 11a. In a departure from this, the construction and the effect in the regions 11b, 11c, 11d can differ from this analogously to the region 11a. It is furthermore conceivable that in the regions 11a, 11b, 11c, 11d, the construction and the effect are at least partially the same.

The regions 11a, 11b, 11c, 11d can furthermore be arranged independently of the segments 1a, 1b. Moreover, a plurality of segments 1a, 1b can, for example, be assigned to one of the regions 11a, 11b, 11e, 11d. Furthermore, a plurality of regions 11a, 11b, 11c, 11d can, for example, be assigned to one of the segments 1a, 1b.

In this context, it is for instance conceivable to locate a plurality of regions 11a, 11b, 11e, 11d of different effect in an ordered structure and for instance to assign them to the segment 1a. Advantageously, the light-emitting device 1 can thus have first emission characteristics in operation and second emission characteristics when it is not in operation. For example, these characteristics can be superimposed on one another to the observer in the event of high frequency triggering of the light-emitting device.

In particular in this context, the use of different light sources and color filters can be dispensed with, so that a contribution is made to high lateral resolution of the light-emitting device 1 as well as to its economical production. Advantageously, a lateral generation of signatures on a single OLED is made possible. The light-emitting device is in particular simple to produce, and in particular for each segment, various emission characteristics can be established, such as color, angle dependency, and brightness. Small dimensions that can be achieved by means of microcavities make especially precise imaging of signatures possible. Chronologically different triggering is possible by means of single contacting of the segments. An angle-dependent change in the appearance of the light-emitting device 1 can in particular also occur in the off state.

1-20. (canceled)

21. A method for producing a light-emitting device having at least two laterally arranged regions of differing optical thicknesses, the method comprising:
providing a carrier layer comprising a substrate;
applying a first electrode layer;
applying a layer sequence for generating light;
applying a second electrode layer; and
structuring at least one layer for varying an optical thickness in a first region of the light-emitting device differently from the layer in a second region of the light-emitting device, wherein the second region is laterally arranged relative to the first region.

22. The method according to claim 21, further comprising inserting an interlayer, extending laterally over the first region, into the layer sequence for varying the optical thickness of the first region.

23. The method according to claim 21, wherein a thickness in a vertical direction of at least one layer in the first region is constructed differently from a thickness in a vertical direction of the layer in the second region.

24. The method according to claim 23, wherein a growth rate of the layer in the first region is different from a growth rate of the layer in the second region.

25. The method according to claim 21, further comprising applying an auxiliary layer to a side of the light-emitting device facing away from the carrier layer, wherein the auxiliary layer comprises a substrate.

26. The method according to claim 21, wherein a first microcavity structure for varying the optical thickness in the first region is constructed on a surface of the substrate in the first region.

27. The method according to claim 21, wherein a second microcavity structure for varying the optical thickness in the first region is constructed inside the substrate in the first region.

28. A light-emitting device having at least two laterally arranged regions of differing optical thicknesses, the light-emitting device comprising:
a carrier layer comprising a substrate;
a first electrode layer;
a layer sequence for generating light; and
a second electrode layer;
wherein the carrier layer, the first electrode layer, the layer sequence, and the second electrode layer are arranged one above the other in a vertical direction,
wherein an optical thickness of at least one layer in a first region of the light-emitting device is constructed differently from an optical thickness of the layer in a second region of the light-emitting device that is laterally arranged relative to the first region.

29. The light-emitting device according to claim 28, wherein the layer sequence comprises an interlayer, and wherein the interlayer extends laterally over the first region.

30. The light-emitting device according to claim 28, wherein a thickness in a vertical direction of at least one layer in the first region is constructed differently from a thickness in a vertical direction of the layer of the second region.

31. The light-emitting device according to claim 28, further comprising an auxiliary layer having a substrate, wherein the auxiliary layer is arranged on a side of the light-emitting device facing away from the carrier layer.

32. The light-emitting device according to claim 28, wherein a surface of the substrate in the first region has a first microcavity structure unlike a surface of the substrate in the second region.

33. The light-emitting device according to claim 28, wherein the substrate in the first region has a second microcavity structure unlike the substrate in the second region.

34. The light-emitting device according to claim 28, wherein the light-emitting device is configured to differ in:
a brightness of light emitted by the light-emitting device; and/or
a color of light emitted by the light-emitting device; and/or
a direction of light emitted by the light-emitting device in the regions of the different optical thicknesses.

35. The light-emitting device according to claim 28, wherein the light-emitting device is configured to differ in:
a brightness of light reflected by the light-emitting device; and/or
a color of light reflected by the light-emitting device; and/or
a direction of light reflected by the light-emitting device in the regions of the different optical thicknesses.

36. The light-emitting device according to claim 28, wherein a number of regions of the differing optical thicknesses amounts to less than 100.

37. The light-emitting device according to claim 28, wherein a color of light emitted by the light-emitting device is the same, in at least one direction, in each of the regions of the differing optical thicknesses.

38. The light-emitting device according to claim 28, wherein a composition of at least one of the layers in the regions of the different optical thicknesses is the same.

39. The light-emitting device according to claim 28, wherein the light-emitting device comprises at least two laterally arranged segments that are operable separately from one another.

40. The light-emitting device according to claim 39, wherein at least one region is assigned to at least one segment.

41. A method for producing a light-emitting device having at least two laterally arranged regions of differing optical thicknesses, the method comprising:
providing a carrier layer comprising a substrate;
applying a first electrode layer;
applying a layer sequence for generating light;
applying a second electrode layer; and
structuring at least one layer for varying an optical thickness in a first region of the light-emitting device differently from the layer in a second region of the light-emitting device,
wherein the second region is laterally arranged relative to the first region,
wherein an interlayer extends laterally over the first region for varying the optical thickness in the first region, and
wherein the interlayer is a transparent metal layer.
